(19) United States
(12) Patent Application Publication
(10) Pub. No.: US 2024/0203851 A1
(43) Pub. Date: Jun. 20, 2024

(54) Semiconductor Device Package with Coupled Substrates

(71) Applicant: Western Digital Technologies, Inc., San Jose, CA (US)

(72) Inventors: Guru Prasada Rao Amberkar, Bangalore (IN); Mahesh A, Bangalore (IN); Kuruba Anjaneyulu, Bangalore (IN)

(73) Assignee: Western Digital Technologies, Inc., San Jose, CA (US)

(21) Appl. No.: 18/361,118

(22) Filed: Jul. 28, 2023

Related U.S. Application Data
(60) Provisional application No. 63/387,328, filed on Dec. 14, 2022.

(51) Int. Cl. H01L 23/498; H01L 23/00; H01L 23/367; H01L 23/373; H01L 25/065

(52) U.S. Cl. CPC H01L 23/49822; H01L 23/3677; H01L 23/3735; H01L 24/32; H01L 25/0657; H01L 2224/32225; H01L 2225/06555; H01L 2924/1434

(57) ABSTRACT

A semiconductor device package includes a first substrate and receiving ports electrically connected to the first substrate. First semiconductor dies are electrically connected to and mounted directly on the first substrate. A second substrate is electrically connected to the first substrate via a corresponding receiving port and is oriented generally perpendicular to the first substrate. Second semiconductor dies are electrically connected to and mounted directly on the second substrate. A housing substantially encloses each of the above mentioned components. The receiving ports allow for additional substrates carrying semiconductor memory dies to be connected to the first substrate thereby increasing the total storage capacity of the semiconductor device package while conforming to a predefined form factor.

### CROSS-REFERENCE TO RELATED APPLICATIONS

This application claims the benefit of U.S. Provisional Patent Application No. 63/387,328 filed Dec. 14, 2022 entitled “Semiconductor Device Package with Coupled Substrates”, which is incorporated by reference herein in its entirety.

### BACKGROUND

The present invention generally relates to semiconductor devices and more particularly to semiconductor device packages having one or more substrates directly coupled to a primary substrate to increase the storage capacity within a predetermined form factor.

Semiconductor device packages often include multiple semiconductor dies and other electrical components coupled to a substrate, such as a printed circuit board (PCB), that is enclosed within an outer housing structure. For a Solid State Drive type (SSD) package, there are typically one or more storage means (e.g., NAND dies) electrically connected to the PCB, each providing an amount of storage that is at least a portion of the total storage capacity of the semiconductor device package. The dimensions of the semiconductor device packages are often constrained by industry-standard form factors based on the intended use of the semiconductor device packages. Some such form factors may be an Enterprise and Data Center Standard Form Factor (EDSFF), such as an E1.S standard form factors, which each define the length, width, and thickness of the package. The E1.S standard form factors commonly include the following: E1.S Bare PCB 5.9 mm, E1.S with heat sink 8 mm, E1.S with symmetric enclosure 9.5 mm, E1.S with asymmetric enclosure 15 mm, and E1.S with asymmetric enclosure 25 mm.

Each of the above mentioned form factors include different advantages and disadvantages. For example, within a single server rack (e.g., a storage server rack) the number of Bare PCB 5.9 mm and symmetric enclosure 9.5 mm form factor semiconductor device packages that may be included is greater than the number of asymmetric enclosure 15 mm and/or 25 mm form factor semiconductor device packages that may be included. As such, by including conventional 5.9 mm and 9.5 mm form factor semiconductor device packages the total storage capacity offered by a single storage server rack may be increased when compared to including conventional 15 mm and 25 mm form factor packages. However, 15 mm and 25 mm form factor packages typically offer better power and performance per package when compared to the 5.9 mm and 9.5 mm packages. For example, the cooling requirements (e.g., via airflow) of the 15 mm and 25 mm packages is lesser than the cooling requirements of the 5.9 mm and 9.5 mm packages. As such, there is a need to increase the total amount of storage capacity offered by the E1.S 15 mm and 25 mm form factor semiconductor device packages while adhering to the form factor dimensions and maintaining the power and performance benefits thereof.

### SUMMARY

In one embodiment there is semiconductor device package including a first substrate having a top planar surface and a bottom planar surface, one or more receiving ports mounted on the top planar surface and electrically connected to the first substrate, one or more first semiconductor dies electrically connected to and mounted directly on the first substrate, a second substrate having a top planar surface and a bottom planar surface, the second substrate being electrically connected to a corresponding receiving port of the one or more receiving ports, the top planar surface of the second substrate being oriented generally perpendicular to the top planar surface of the first substrate, one or more second semiconductor dies electrically connected to and mounted directly on the second substrate, and a housing substantially enclosing each of the first substrate, the second substrate, the one or more receiving ports, the one or more first semiconductor dies, and the one or more second semiconductor dies.

In some embodiments, the housing has a width of about 33.75 mm, a length of about 118.75 mm and a height of about 25.00 mm. In some embodiments, the one or more first semiconductor dies and one or more second semiconductor dies include NAND dies. In some embodiments, there are at least twice as many second semiconductor dies as first semiconductor dies. In some embodiments, the one or more receiving ports includes a first receiving port and a second receiving port each electrically connected to the first substrate and spaced from one another. In some embodiments, the semiconductor device package further includes a third substrate, wherein the second substrate is electrically connected to the first receiving port and the third substrate electrically is connected to the second receiving port.

In some embodiments, the one or more second semiconductor dies are electrically connected to and mounted directly on the second substrate, and the semiconductor device package further includes one or more third semiconductor dies electrically connected to and mounted directly on the third substrate. In some embodiments, the housing substantially encloses each of the first, second, and third substrates and each of the one or more first, second, and third semiconductor dies, and the housing includes a bottom surface and a top surface, the first substrate being positioned between the bottom surface and top surface of the housing, a first hollow protrusion extending upwardly from the top surface of the housing proximate the first receiving port, the second substrate and the one or more second semiconductor dies being at least partially positioned within the first hollow protrusion, and a second hollow protrusion extending upwardly from the top surface of the housing proximate the second receiving port, the third substrate and the one or more third semiconductor dies being at least partially positioned within the second hollow protrusion.

In some embodiments, the semiconductor device package further includes a heat sink mounted on the top surface of the housing and including a plurality of fins, each of the plurality of fins being positioned between the first and second hollow protrusions of the housing. In some embodiments, the heat sink is integrally formed with the housing. In some embodiments the semiconductor device package further includes a thermally conductive layer, each thermally conductive layer of the one or more thermally conductive layers mounted directly onto a surface of a corresponding semiconductor die of the one or more first, second, and third semiconductor dies. Each thermally conductive layer may extend between the surface of the corresponding semiconductor die to an adjacent interior surface of the housing. In some embodiments, each fin of the plurality of fins extend upwardly from the top surface of the housing and are generally perpendicular to the top surface of the housing. In some embodiments, the second substrate and third substrate are detachably coupled to the first substrate by the one or more receiving ports.

In some embodiments, the first and second hollow protrusions each have a width that is greater than a width of an individual fin of the plurality of fins. In some embodiments, the semiconductor device package further includes one or more first fasteners connected to the second substrate and the first hollow protrusion, the one or more first fasteners connected to the second substrate opposite where the second substrate is electrically connected to the first receiving port and one or more second fasteners connected to the third substrate and the second hollow protrusion, the one or more second fasteners connected to the third substrate opposite where the third substrate is electrically connected to the second receiving port. In some embodiments, the one or more first fasteners and the one or more second fasteners include biasing elements configured to retain the orientation of the second substrate and third substrate relative to the first substrate. In some embodiments, the one or more receiving ports are each through hole mounts electrically connected to the first substrate.

In another embodiment, there is a semiconductor device package including a first substrate means for providing electrical communication to one or more electrical components coupled to the first substrate means, one or more receiving means electrically connected to the first substrate means and for providing electrical communication between the first substrate means and one or more other substrate means, one or more first storage means each for storing an amount of electrical charge, each of the one or more first storage means being electrically connected to the first substrate means by a respective electrical connection means, a second substrate means for providing electrical communication to one or more electrical components coupled to the second substrate means, the second substrate means being electrically connected to the one or more receiving means and oriented generally perpendicular to the first substrate means, one or more second storage means each for storing an amount of electrical charge, each of the one or more second storage means being electrically connected to the second substrate means by a respective electrical connection means, and a housing means for substantially enclosing each of the first substrate means, the second substrate means, the one or more receiving means, the one or more first storage means, and the one or more second storage means.

In some embodiments, the semiconductor device package further includes a third substrate means for providing electrical communication to one or more electrical components coupled to the third substrate means, the third substrate means being electrically connected to the one or more receiving means and oriented generally perpendicular to the first substrate means and spaced from the second substrate means, and one or more third storage means each for storing an amount of electrical charge, each of the one or more third storage means being electrically connected to the third substrate means by a respective electrical connection means.

In another embodiment there is a semiconductor device package including a first substrate having a top planar surface and a bottom planar surface substantially parallel to the top planar surface, a first receiving port electrically connected to the first substrate, a second receiving port spaced from the first receiving port and electrically connected to the first substrate, one or more first NAND dies electrically connected to and mounted directly on the first substrate, a second substrate having a top planar surface and a bottom planar surface, the second substrate electrically connected to the first receiving port such that the top planar surface of the second substrate is generally perpendicular to the top planar surface of the first substrate, one or more second NAND dies electrically connected to and mounted directly on the second substrate, a third substrate having a top planar surface and a bottom planar surface, the third substrate electrically connected to the second receiving port such that the top planar surface of the third substrate is generally perpendicular to the top planar surface of the first substrate, one or more third NAND dies electrically connected to and mounted directly on the third substrate, and a housing substantially enclosing each of the first, second, and third substrates and each of the one or more first, second, and third NAND dies.

The housing includes a bottom surface and a top surface, the first substrate being positioned between the bottom surface and top surface of the housing, a first hollow protrusion extending upwardly from the top surface of the housing proximate the first receiving port, the second substrate being at least partially positioned within the first hollow protrusion, and a second hollow protrusion extending upwardly from the top surface of the housing proximate the second receiving port, the third substrate being at least partially positioned within the second hollow protrusion. There is a heat sink mounted on the top surface of the housing and including a plurality of fins, each of the plurality of fins being positioned between the first and second hollow protrusions of the housing.

### BRIEF DESCRIPTION OF THE DRAWINGS

The foregoing summary, as well as the following detailed description, will be better understood when read in conjunction with the appended drawings. For the purpose of illustrating the present disclosure, there are shown in the drawings embodiments, which are presently preferred, wherein like reference numerals indicate like elements throughout. It should be noted, however, that aspects of the present disclosure can be embodied in different forms and thus should not be construed as being limited to the illustrated embodiments set forth herein. The elements illustrated in the accompanying drawings are not necessarily drawn to scale, but rather, may have been exaggerated to highlight the important features of the subject matter therein. Furthermore, the drawings may have been simplified by omitting elements that are not necessarily needed for the understanding of the disclosed embodiments.

In the drawings:

FIG. 1 is a cross-sectional view of a semiconductor device package in accordance with an exemplary embodiment of the present disclosure;

FIG. 2 is a perspective view of the first, second and third substrates of the semiconductor device package of FIG. 1;

FIG. 3 is a cross-sectional view of the semiconductor device package of FIG. 1 with dimensions illustrated;

FIG. 4 is a perspective view of the semiconductor device package of FIG. 1;

FIG. 5A is a top plan view of the first substrate of the semiconductor device package of FIG. 1; and

FIG. 5B is a top elevational view of the second substrate of the semiconductor device package of FIG. 1.

### DETAILED DESCRIPTION

The present subject matter will now be described more fully hereinafter with reference to the accompanying Figures, in which representative embodiments are shown. The present subject matter can, however, be embodied in different forms and should not be construed as limited to the embodiments set forth herein. Rather, these embodiments are provided to describe and enable one of skill in the art.

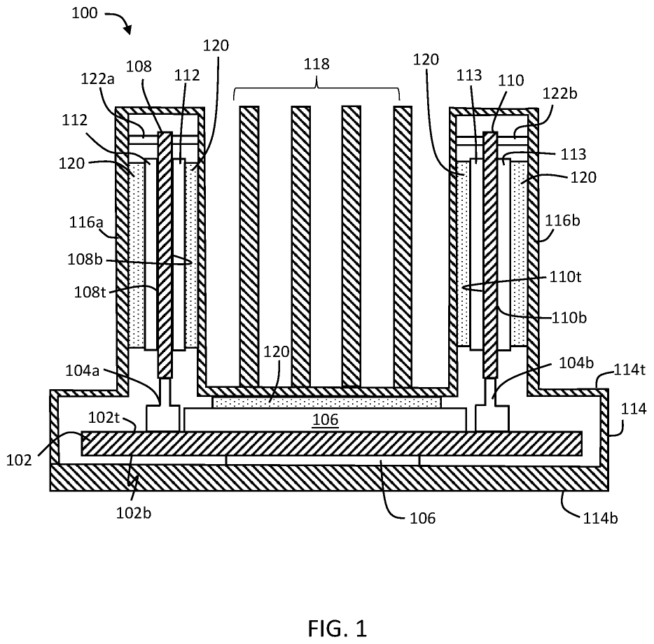

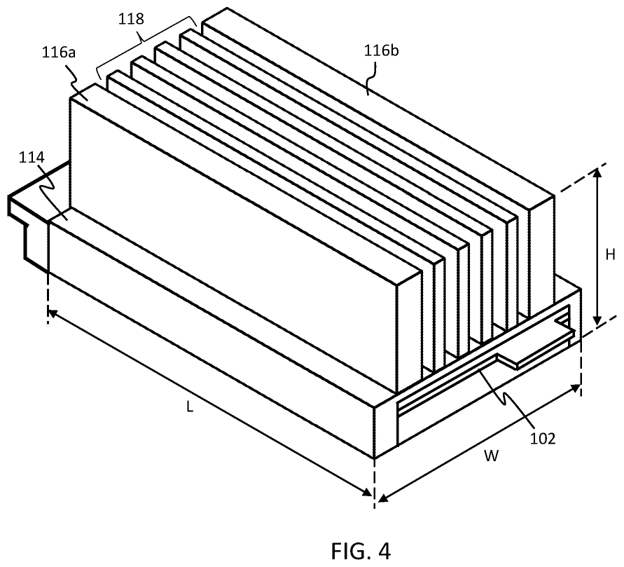

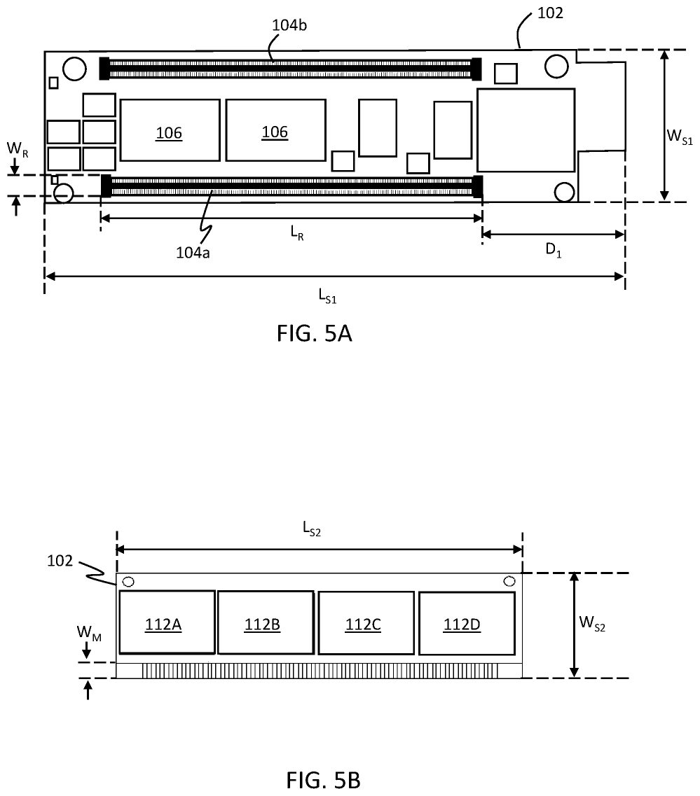

Referring to FIGS. 1-5B, there is shown a semiconductor device package, generally designated 100, in accordance with an exemplary embodiment of the present disclosure. The semiconductor device package 100, or package 100 for short, may be configured to provide an increased storage capacity while adhering to one or more industry standard form-factors, when compared to conventional semiconductor device packages adhering to the same industry standard form-factor. For sake of brevity, the semiconductor device package 100 is described herein with reference to the E1.S 25 mm industry standard form-factor dimensions. However, it will be understood that the inventive concepts discussed herein may be applied to other industry standard form-factors in order to provide an increased total storage capacity.

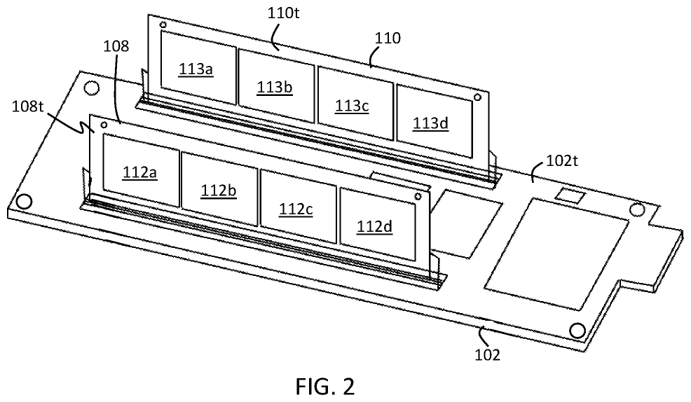

Referring to FIGS. 1-2, the semiconductor device package 100 may include a first substrate 102, one or more receiving ports 104, one or more first semiconductor dies 106, a second substrate 108, a third substrate 110, one or more second semiconductor dies 112, one or more third semiconductor dies 113 and a housing 114 substantially enclosing each. In some embodiments, one or more of the first substrate 102, second substrate 108, and third substrate 110 are for providing storage means, processing means and/or control means. For example, the first substrate 102 may be for providing storage means, processing means and control means and the second and third substrates 108, 110 may be for providing additional storage means. The first substrate 102 may have a top planar surface 102t and a bottom planar surface 102b substantially parallel to the top planar surface 102t. In some embodiments, the one or more first semiconductor dies 106 may be a first set of semiconductor dies 106. Similarly, the one or more second semiconductor dies 112 and the one or more third semiconductor dies 113 may be a second and third set of semiconductor dies 112, 113 respectively. Each first, second, and third set of semiconductor dies 106, 112, 113 may refer to the semiconductor dies mounted on the corresponding first, second and third substrates 102, 108, 110. In some embodiments, one or more sets of the semiconductor dies 106, 112, 113 are included within a NAND package that is mounted on a surface of the corresponding substrate 102, 108, 110.

The first substrate 102 may include a mechanical base support for the electrical components connected thereto and an electrical interface (or electrical circuit) that provides access to said electrical components. In some embodiments, the first substrate 102 may include an electrical circuit (not shown) having a plurality of metal layers and/or traces disposed within the first substrate 102, including one or more layers for routing signals such as, but not limited to, input/output signals, power signals, and ground signals using conductive (e.g., copper) traces. In some embodiments, the first substrate 102 includes, for example, up to sixteen layers for routing signals. In some embodiments, the first substrate 102 is a first printed circuit board (PCB). In some embodiments, the first substrate is a high-density interconnect (HDI) PCB. In some embodiments, the second substrate 108 and/or third substrate 110 are substantially the same as the first substrate 102. In some embodiments, the second and third substrates 108, 110 have a thickness that is less than the first substrate 102. For example, the second and third substrates 108, 110 may each have a thickness that is about half the thickness of the first substrate 102. In some embodiments, the second substrate 108 and/or third substrate 110 have a thickness of less than or equal to about 1 mm.

In some embodiments, the one or more receiving ports 104 includes a first receiving port 104a and a second receiving port 104b configured to electrically connect the second and third substrates 108, 110 to the first substrate 102, respectively. The first receiving port 104a and/or second receiving port 104b may be electrically connected to and mounted directly on the first substrate 102. For example, the first receiving port 104a and second receiving port 104b may be electrically connected to and mounted directly on a top planar surface 102t of the first substrate 102. In some embodiments, the first substrate 102 includes one or more surface mount technology (SMT) or through hole (TH) receptacles that the first and second receiving ports 104a, 104b are electrically connected to. In some embodiments there may be one or more through hole (TH) mounting supports connected to the first and second receiving ports 104a, 104b respectively. For example, the receiving ports 104a, 104b may be TH mounts electrically connected to the first substrate 102. In some embodiments, the first substrate 102 includes two on-board SMT receptacles with TH mounting supports to route electrical signals to and from the first substrate 102 (e.g., electrical signals from and to the second and third substrates 108, 110). In some embodiments, each of the first receiving port 104a and the second receiving port 104b includes a female electrical and mechanical connector configured to receive a corresponding male connector of the second and third substrates 108, 110 respectively. The receiving ports 104a, 104b are configured to permit electrical signals to be conveyed between components on the first substrate 102 (e.g., first semiconductor dies 106) and components of second and third substrates 108, 110 (e.g., second semiconductor dies 112, and third semiconductor dies 113).

In some embodiments, the second substrate 108 and third substrate 110 are oriented generally perpendicular to the first substrate 102. The second substrate 108 may include a top planar surface 108t and a bottom planar surface 108b, that may be, in some embodiments, oriented generally perpendicular to the top planar surface 102t of the first substrate 102. For example, one or more of the top planar surface 108t and bottom planar surface 108b may extend along a plane that is generally perpendicular to the plane the top planar surface 102t of the first substrate extends along. Similarly, the third substrate 110 may include a top planar surface 110t and a bottom planar surface 110b at least one of which may be oriented generally perpendicular to the top planar surface 102t of the first substrate 102. In some embodiments, the second and/or third substrate 108, 110 are detachably coupled to the first substrate 102 by the respective receiving ports 104a, 104b.

The housing 114 may include one or more inner surfaces defining an interior cavity or recess of the housing within which at least a portion of the first substrate 102, one or more receiving ports 104a or 104b, one or more first semiconductor dies 106, second substrate 108, third substrate 110, and the one or more second and third semiconductor dies 112, 113 may be positioned. As such the housing 114 may be configured to protect the above-mentioned components from external forces and/or to keep debris from entering into the housing 114. In some embodiments, the housing 114 is comprised of one or more of a polymer, metal, metal alloy, plastic, and/or a composite material. The housing 114 may substantially enclose the first, second and third substrates 102, 108, 110 while allowing for the first substrate 102 to be electrically connected to one or more external devices. For example, a portion of the first substrate 102 configured to be electrically connected to an external device may extend partially out of the housing 114. The housing 114 may substantially enclose each of the first substrate 102, the second substrate 108, the third substrate 110, the receiving ports 104a, 104b, the one or more first semiconductor dies 106 and the one or more second and/or third semiconductor dies 112, 113.

In some embodiments, the housing 114 includes a bottom surface 114b and a top surface 114t, generally parallel to and spaced from the top surface 114t. In some embodiments, the bottom surface 114b and top surface 114t define, at least partially, a first inner chamber within which one or more components of the semiconductor device package 100 may be positioned. The first substrate 102 may be positioned within the housing 114 at least partially between the top and bottom surfaces 114t, 114b. In some embodiments, one or more of the first semiconductor dies 106 are positioned between the top surface 114t and bottom surface 114b of the housing 114. The housing 114 may be configured to enclose the second and third substrates 108, 110 when the second and third substrates 108, 110 are electrically connected to the first substrate 102 (e.g., when the second and third substrates 108, 110 are connected to receiving ports 104a, 104b). The housing 114 may include a first protrusion 116a and/or a second protrusion 116b extending upwardly from the top surface 114t of the housing 114 and configured to enclose the second and third substrates 108, 110. The first protrusion 116a may be positioned proximate the first receiving port 104a and the second protrusion 116b may be positioned proximate the second receiving port 104b. In some embodiments, the first protrusion 116a and/or second protrusion 116b extend generally perpendicular from the top surface 114t of the housing 114. For example, the side surfaces of the first protrusion 116a and/or second protrusion 116b may be oriented on respective planes that are generally perpendicular to the plane on which the top surface 114t of the housing 114 is oriented.

By including the second and/or third substrates 108, 110 and orienting the second and/or third substrates 108, 110 generally perpendicular to the first substrate 102 the semiconductor device package 100 of the present disclosure may increase the amount of available space within which memory dies may be connected when compared to conventional semiconductor device packages of generally the same size. For example, in conventional semiconductor device packages conforming to an E1.S 25 mm form factor, a single substrate is provided that is positioned within a housing in generally the same manner as the first substrate 102. All of the memory dies as well as other semiconductor dies are electrically connected and mounted to the single substrate of the conventional semiconductor device package. The number and/or placement of memory dies mounted thereon is based on maximizing the number of memory dies that may be mounted directly on the single substrate along with other necessary dies and/or electrical components. For example, in a conventional substrate included in an E1.S 25 mm form factor semiconductor device package, the number of memory dies mounted thereon may be up to about eight.

However, in the semiconductor device package 100 of the present invention, the number of memory dies mounted on the first substrate 102 may be less than what is conventionally included (e.g., less than eight) such that the receiving ports 104a, 104b may be mounted on the first substrate 102. In this manner, the second and/or third substrates 108, 110 may be electrically connected to the first substrate 102 and positioned within the protrusions 116a, 116b of the housing 114. As such, the second and/or third substrates 108, 110 may provide additional mounting surfaces (e.g., the top surface 108t, 110t, and bottom surface 108b, 110b) upon which memory dies (e.g., the second and third semiconductor dies 112, 113) may be mounted. Thus, in some embodiments, even though the number of memory dies on first substrate 102 may be less than the number of memory dies positionable on the single substrate of certain conventional devices, the total number of memory dies in the present semiconductor device package may be greater due to the additional memory devices on the second and third substrates 108, 110. Further to the example above, there may be eight memory dies mounted to each of the second and third substrate 108, 110 and four memory dies mounted to the first substrate 102. As such, when compared to conventional semiconductor device packages of the same form factor (e.g., E1.S 25 mm) the overall storage capacity and/or number of memory dies is improved by at least about 150% (e.g., eight dies in the conventional package as compared to the twenty of the package 100). In instances where asymmetric die loading is implemented, the total storage capacity may be increased by at least about 350% when compared to conventional semiconductor device packages of the same form factor. In this manner, the semiconductor device package 100 of the present disclosure may provide an increased storage capacity when compared to conventional semiconductor device packages of the same, or a similar, industry standard-form factor.

In some embodiments, the semiconductor device package 100 includes a heat sink 118 mounted on the top surface 114t of the housing 114 and configured to dissipate heat generated by the electrical components of the semiconductor device 100 during use. The heat sink 118 may be a fin heat sink including a plurality of fins. For example, in FIG. 1, the heat sink 118 includes four fins positioned between the first and second protrusions 116a, 116b of the housing 114. The fins of heat sink 118, in some embodiments, may be substantially parallel to the first and second protrusions 116a, 116b. Moreover, in some embodiments, the fins of heat sink 118 may have substantially the same height as the first and second protrusions 116a, 116b. In some embodiments, the heat sink 118 may include any number of fins. For example, the heat sink 118 may include one fin, two fins, three fins, four fins, five fins, six fins, seven fins, eight fins, or more than eight fins. In some embodiments, each of the first and second protrusions 116a, 116b may act as additional fins to help dissipate heat together with the heat sink 118. In some embodiments, while first and second protrusions each has an internal cavity for holding the second and third substrates 108, 110, the fins of heat sink 118 may be solid. In some embodiments, each of the fins of the heat sink 118 are oriented generally perpendicular to the top surface 114t of the housing 114. In some embodiments, the heat sink 118 is integrally formed with the housing 114. For example, each of the fins included in the heat sink 118 may be integrally formed with the housing 114. In some embodiments, the first and second protrusions 116a, 116b are integrally formed with the top surface 114t of the housing 114.

In some embodiments, the first protrusion 116a and/or second protrusion 116b are hollow such that one or more of the second and third substrates 108, 110 and the components connected thereto, may be positioned at least partially within the corresponding first and second protrusions 116a, 116b. For example, the first substrate 108 may be at least partially positioned within the hollow recess defined by the first protrusion 116a and the second substrate 110 may be at least partially positioned within the hollow recess defined by the second protrusion 116b.

The one or more first semiconductor dies 106, second semiconductor dies 112, and/or third semiconductor dies 113 may be any type of semiconductor dies, such as, but not limited to, memory dies (e.g., NAND dies), application specific integrated circuit (ASIC) dies, controller dies, or other integrated circuit (IC) dies. For example, in some embodiments, there is at least one controller and one or more NAND dies directly coupled to the first substrate 102. In some embodiments, the plurality of first semiconductor dies 106 may include dies of different types. For example, the semiconductor dies may include a plurality of memory dies and one or more control dies electrically connected to the first substrate 102. In some embodiments, the one or more first semiconductor dies 106 is a NAND package including a plurality of memory dies that may be electrically connected to the package via any conventional methods (e.g., wire bond, flip-chip mounting) known to those skilled in the art. The NAND package may be electrically connected to the first substrate 102 via soldering. In some embodiments, the one or more second semiconductor dies 112 and/or third semiconductor dies 113 are NAND dies.

Still referring to FIGS. 1-2, in some embodiments, one or more of the first semiconductor dies 106 are mounted directly on the first substrate 102. At least one of the first semiconductor dies 106 may be electrically connected to the first substrate 102 and mounted on the top planar surface 102t. In some embodiments, at least one of the first semiconductor dies 106 is electrically connected to the first substrate 102 and mounted on the bottom planar surface 102b. In some embodiments, at least one of the first semiconductor dies 106 is mounted on the top planar surface 102t and at least one or more other first semiconductor dies 106 is mounted on the bottom planar surface 102b. In some embodiments, one or more of the first semiconductor dies 106 is positioned on the first substrate 102 between the first receiving port 104a and second receiving port 104b. In some embodiments, there are between one to six first semiconductor dies 106 (e.g., memory dies, NAND dies) electrically connected to and mounted directly on the first substrate 102. In some embodiments, there are four first semiconductor dies 106 (e.g., memory dies, NAND dies) electrically connected to and mounted directly on the first substrate 102. There may be other electrical components such as, but not limited to, ASIC dies, controllers, dynamic random access memory (DRAM), capacitors, and/or other control circuits electrically connected to the first substrate 102. The specific number and/or types of other electrical components connected thereto may vary based on the architecture of the package 100.

In some embodiments, the one or more second semiconductor dies 112 are mounted directly on the second substrate 108. At least one of the second semiconductor dies 112 may be electrically connected to the second substrate 108 and mounted directly on the top planar surface 108t and/or bottom surface 108b. In some embodiments, there are one or more of the second semiconductor dies 112 mounted on the top planar surface 108t and bottom planar surface 108b of the second substrate 108. For example, there may be four second semiconductor dies 112a-112d mounted on the top planar surface 108t and there may be four second semiconductor dies 112 mounted on the bottom planar surface 108b. In some embodiments, the number of second semiconductor dies 112 included in the semiconductor device package 100 is greater than the number of first semiconductor dies 106 included. In some embodiments, there are at least twice as many second semiconductor dies 112 as first semiconductor dies 106. For example, there may be four first semiconductor dies 106 (e.g., four first NAND dies) mounted on the first substrate 102 and eight second semiconductor dies 112 (e.g., eight second NAND dies) mounted on the second substrate 108. In some embodiments, there are at least four second semiconductor dies 112 mounted to and electrically connected to the second substrate 108.

In some embodiments, the one or more third semiconductor dies 113 are mounted directly on the third substrate 110. The number and/or mounting locations of the third semiconductor dies 113 with respect to the third substrate 110 may be generally the same as described in the preceding paragraph with reference to the second semiconductor dies 112 and the second substrate 108 and will not be described again for sake of brevity. There may be at least twice as many third semiconductor dies 113 as first semiconductor dies 106. For example, there may be four first semiconductor dies 106 (e.g., four first NAND dies) mounted on the first substrate 102 and eight third semiconductor dies 113 (e.g., eight third NAND dies) mounted on the third substrate 108. For example, there may be at least four third semiconductor dies 113a-113d mounted on the top surface 110t of the third substrate 110 and four third semiconductor dies 113 mounted on the bottom surface 110b. In some embodiments, the number of second semiconductor dies 112 and third semiconductor dies 113 mounted to the respective second and third substrates 108, 110 is generally the same. In some embodiments, the second semiconductor dies 112 are arranged symmetrically on the second substrate 108 with respect to the top and bottom planar surfaces 108t, 108b. The third semiconductor dies 113 may be arranged symmetrically on the third substrate 108 with respect to the top and bottom planar surfaces 110t, 110b.

In some embodiments, there may be one or more thermally conductive layers 120 mounted on a surface of one or more of the first, second, and/or third semiconductor dies 106, 112, 113. The thermally conductive layers 120 may be comprised of a thermally conductive material having a thermal conductivity of at least 0.01 W/cm*K. In some embodiments, the thermally conductive layers 120 are thermal interface materials (TIMs). In some embodiments, the thermally conductive layers 120 are a thermally conductive adhesive that is applied to a surface of one or more of the first, second, and/or third semiconductor dies 106, 112, 113. In some embodiments, the thermally conductive layers 120 are comprised of a silicone polymer. In other embodiments, the thermally conductive layers 120 are comprised of a metal or metal alloy (e.g., copper, aluminum). In some embodiments, the thermally conductive layers 120 extend between the surface of the corresponding semiconductor die 106, 112, 113 to which they are mounted and an adjacent surface of the housing 114. For example, the thermally conductive layer 120 mounted on the first semiconductor die 106 illustrated in FIG. 1 extends from the top surface of the first semiconductor die 106 to the adjacent inner surface of the housing 114 proximate the top planar surface 114t. Similarly, the thermally conductive layers 120 mounted on the second and thirds semiconductor dies 112, 113, respectively, extend from an outer surface of the semiconductor dies 112, 113 to an inner surface of the corresponding first and second protrusions 116a, 116b.

In some embodiments, there may be one or more fasteners 122a, 122b, connected to the second and third substrate 108, 110 respectively and configured to maintain the position of the second and third substrates 108, 110 relative to the housing 114. There may be one or more first fasteners 122a connected to the second substrate 108 and the first protrusion 116a. The fasteners 122a, 122b may connect to the inner surface of the protrusions 116a, 116b. The one or more first fasteners 122a may be connected to the second substrate 108 at a position generally opposite where the second substrate 108 is electrically connected to the first receiving port 104a. For example, and as illustrated in FIG. 1, the first fastener 122a is located proximate a side of the second substrate 108 opposite the side where the second substrate 108 is connected to the first receiving port 104a. In some embodiments, the one or more first fasteners 122a are connected to the first protrusion 116a. In this manner, the one or more first fasteners 122a may aid in maintaining the spacing of the second substrate 108 from the inner surfaces of the first protrusion 116a. In some embodiments, the one or more first fasteners 122a act as an electrical ground. In some embodiments, there are between one to four first fasteners 122a connected to the second substrate 108 and/or first protrusion 116a. In some embodiments, there are two fasteners 122a connected to the second substrate 108 and/or first protrusion 116a. In some embodiments, the one or more first fasteners 122a are biasing elements. For example, the one or more first fasteners 122a may each include a spring to aid in coupling the first fastener(s) 122a to the second substrate 108. For example, each fastener may include a spring positioned between an inner surface of the protrusion and at least one of the top and bottom surface of the respective substrate 108, 110. As such, the spring biased fasteners may provide some level of vibration and/or shock absorption capabilities thereby reducing the risk of damage to the substrates 108, 110.

There may be one or more second fasteners 122b connected to the third substrate 110 and/or second protrusion 116b in generally the same manner as described above with reference to the first fasteners 122a, second substrate 106, and first protrusion 116a. As such, for sake of brevity and so as not to obscure pertinent aspects of the present disclosure the one or more second fasteners 112b will not be described in additional detail.

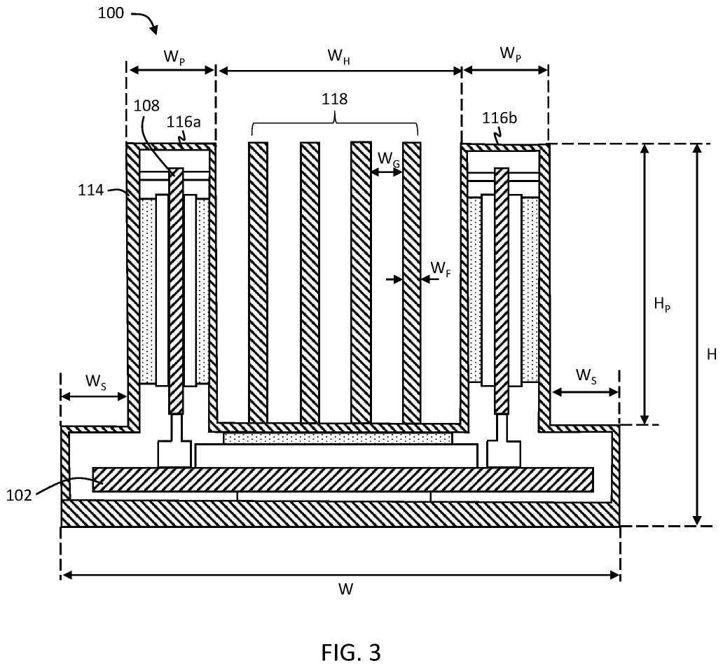

Referring to FIGS. 3-5B, the semiconductor device package 100 and the components thereof may be sized to conform to one or more industry standard form-factors, such as, but not limited to, the E1.S 25 mm form-factor. The housing 114 may have a total width W of about 33.75 mm, a total height H of about 25.00 mm and a total length L of about 118.75 mm. In some embodiments, the height H_{P} from the top surface 114t of the housing 114 to the top surface of the first and/or second protrusions 116a, 116b is about 15.5 mm. In some embodiments, the height H_{P} of the protrusions is generally equal to the height of the fins included in the heatsink 118. In some embodiments. In some embodiments, the first and/or second protrusions 116a, 116b are spaced from a corresponding side surface of the housing 114 by a distance W_{S}. In some embodiments the spacing distance W_{S} is about 5.00 mm. In some embodiments, the first and second protrusions 116a, 116b have a width W_{P} that is greater than a width W_{F} of each fin included in the heat sink 118. In some embodiments, the width W_{P} is about 6.00 mm and the width W_{F} is between about 0.50 mm to about 2.00 mm. In some embodiments, the width W_{F} is between about 0.50 mm to about 1.00 mm.

In some embodiments, each fin included in the heat sink 118 is spaced from each adjacent fin by a distance W_{G}. In some embodiments, the distance between each fin of the heat sink 118 is between about 0.50 mm to about 2.00 mm. In some embodiments, the distance W_{H} between the protrusions 116a, 116b is about 11.75 mm. In some embodiments, the thickness between the inner wall and outer wall of each protrusion 116a, 116b is between about 0.50 mm to about 1.00 mm. In some embodiments, the protrusions 116a, 116b, and/or fins included in the heat sink 118 may have a length that is equal to or less than the length L of the housing 114.

The first substrate 102 may have a length L_{S1} of about 111.50 mm and a width W_{S1} of about 31.50 mm. In some embodiments, the receiving ports 104a and/or 104b may be spaced from a front surface of the first substrate 102 by a distance D₁. In some embodiments, each of the receiving ports 104a and 104b is spaced from the front surface of the first substrate 102 by generally the same distance D₁. The distance D₁ may be less than or equal to 23.00 mm. Each of the receiving ports 104a, 104b may have generally the same length L_{R}. The length of each of the receiving ports 104a, 104b may be between about 75.00 mm to about 79.00 mm. In some embodiments, each of the receiving ports 104a, 104b has a width W_{R} of about 6.00 mm. In some embodiments, each of the receiving ports 104a, 104b is spaced from a corresponding adjacent side surface of the first substrate 102 by less than 1.00 mm. The second substrate 108 may have a total length L_{S2} of about 75.00 mm and a total width W_{S2} of equal to or less than 17.00 mm. In some embodiments, the male electrical connectors of the second substrate 108, configured to be electrically and mechanically connected to the corresponding receiving port 104a, 104b, has a width W_{M} of between about 3.00 mm to about 4.00 mm. The third substrate 110 may have generally the same dimensions as the second substrate 108.

In some embodiments, there may be a number of power, ground, and input/output (IO) pins electrically connected to the first substrate 102 and configured to facilitate electrical communication with the second and third substrates 108, 110 coupled thereto. For example, the receiving ports 104a, 104b may be configured to electrically connect the second and third substrates 108, 110 with the first substrate 102 via the pins (not shown). In some embodiments, for each semiconductor die 112, 113 and/or memory die package (e.g., NAND package) in communication with the substrate 102 via receiving port 104a, 104b, the corresponding receiving port includes about 64 pins. For each NAND channel, about 32 pins may be needed and the total pin count for each of the receiving ports 104a, 104b may be a multiple of 32. The total number of required pins may be reduced by sharing channels between different memory dies (e.g., NAND dies). In some embodiments, there are about 56 pins for IO and electrical ground and about eight power pins for each receiving port 104a, 104b for two NAND channels. In some embodiments, there are two NAND IO voltage (VCC) pins, two NAND Core Voltage pins (VCCQ), two NAND Vpp pins (Vpp), and two Vref pins (e.g., one for a first channel and one for a second channel). In some embodiments, there is an eight pin data bus for a first channel (e.g., channel 0, CH0). In some embodiments, there is a control bus of the first channel having sixteen pins (e.g., control bus of channel-0). In some embodiments, there is an eight pin data bus for a second channel (e.g., channel 1, CH1). In some embodiments, there is a control bus of the second channel having sixteen pins. In some embodiments, there are eight ground pins. In some embodiments, the size of the receiving ports 104a, 104b is dependent upon the number of required pins. For example, the dimensions of the receiving ports 104a, 104b outlined above are based on a 64 pin count, as discussed in this paragraph. However, as the pin count decreases, the size of the receiving ports 104a, 104b may also decrease thereby providing additional space on the first substrate 102 to position additional memory dies and/or NAND packages containing multiple memory dies.

It will be appreciated by those skilled in the art that changes could be made to the exemplary embodiments shown and described above without departing from the broad inventive concepts thereof. It is understood, therefore, that this invention is not limited to the exemplary embodiments shown and described, but it is intended to cover modifications within the spirit and scope of the present invention as defined by the claims. For example, specific features of the exemplary embodiments may or may not be part of the claimed invention and various features of the disclosed embodiments may be combined. The words “right”, “left”, “lower” and “upper” designate directions in the drawings to which reference is made. Unless specifically set forth herein, the terms “a”, “an” and “the” are not limited to one element but instead should be read as meaning “at least one”. As used herein, the term “about” may refer to +/−10% of the value referenced. For example, “about 9” is understood to encompass 8.1 and 9.9.

It is to be understood that at least some of the figures and descriptions of the invention have been simplified to focus on elements that are relevant for a clear understanding of the invention, while eliminating, for purposes of clarity, other elements that those of ordinary skill in the art will appreciate may also comprise a portion of the invention. However, because such elements are well known in the art, and because they do not necessarily facilitate a better understanding of the invention, a description of such elements is not provided herein.

Further, to the extent that the methods of the present invention do not rely on the particular order of steps set forth herein, the particular order of the steps should not be construed as limitation on the claims. Any claims directed to the methods of the present invention should not be limited to the performance of their steps in the order written, and one skilled in the art can readily appreciate that the steps may be varied and still remain within the spirit and scope of the present invention.

What is claimed is:

1. A semiconductor device package comprising:
a first substrate having a top planar surface and a bottom planar surface;
one or more receiving ports mounted on the top planar surface and electrically connected to the first substrate;
one or more first semiconductor dies electrically connected to and mounted directly on the first substrate;
a second substrate having a top planar surface and a bottom planar surface, the second substrate being electrically connected to a corresponding receiving port of the one or more receiving ports, the top planar surface of the second substrate being oriented generally perpendicular to the top planar surface of the first substrate;
one or more second semiconductor dies electrically connected to and mounted directly on the second substrate; and
a housing substantially enclosing each of the first substrate, the second substrate, the one or more receiving ports, the one or more first semiconductor dies, and the one or more second semiconductor dies, the housing comprising:
a bottom surface and a top surface, the first substrate being positioned between the bottom surface and top surface of the housing;
a first hollow protrusion extending upwardly from the top surface of the housing proximate one of the one or more receiving ports, the second substrate and the one or more second semiconductor dies being at least partially positioned within the first hollow protrusion.

2. The semiconductor device package of claim 1, wherein the housing has a width of about 33.75 mm, a length of about 118.75 mm and a height of about 25.00 mm.

3. The semiconductor device package of claim 1, wherein the one or more first semiconductor dies include a first set of NAND dies and the one or more second semiconductor dies include a second set of NAND dies.

4. The semiconductor device package of claim 3, wherein the second set of NAND dies includes at least twice as many NAND dies as the first set of NAND dies.

5. The semiconductor device package of claim 1, wherein the one or more receiving ports includes a first receiving port and a second receiving port each electrically connected to the first substrate and spaced from one another.

6. The semiconductor device package of claim 5 further comprising:
a third substrate, wherein the second substrate is electrically connected to the first receiving port and the third substrate electrically is connected to the second receiving port; and
one or more third semiconductor dies electrically connected to and mounted directly on the third substrate.

7. The semiconductor device package of claim 6, wherein the one or more first semiconductor dies include a first set of NAND dies, the one or more second semiconductor dies include a second set of NAND dies, and the one or more third semiconductor dies include a third set of NAND dies.

8. The semiconductor device package of claim 7, wherein each of the second set of NAND dies and third set of NAND dies includes at least twice as many NAND dies as the first set of NAND dies.

9. The semiconductor device package of claim 6, wherein the housing substantially encloses each of the first, second, and third substrates and each of the one or more first, second, and third semiconductor dies,
wherein the first hollow protrusion is proximate the first receiving port, and
wherein the housing further comprises:
a second hollow protrusion extending upwardly from the top surface of the housing proximate the second receiving port, the third substrate and the one or more third semiconductor dies being at least partially positioned within the second hollow protrusion.

10. The semiconductor device package of claim 9 further comprising:
a heat sink mounted on the top surface of the housing and including a plurality of fins, each of the plurality of fins being positioned between the first and second hollow protrusions of the housing.

11. The semiconductor device package of claim 10, wherein the heat sink is integrally formed with the housing.

12. The semiconductor device package of claim 10 further comprising:
one or more thermally conductive layers, each thermally conductive layer of the one or more thermally conductive layers mounted directly onto a surface of a corresponding semiconductor die of the one or more first, second, and third semiconductor dies,
wherein each thermally conductive layer extends between the surface of the corresponding semiconductor die to an adjacent interior surface of the housing.

13. The semiconductor device package of claim 10, wherein each fin of the plurality of fins extends upwardly from the top surface of the housing and are generally perpendicular to the top surface of the housing.

14. The semiconductor device package of claim 10, wherein the first and second hollow protrusions each have a width that is greater than a width of an individual fin of the plurality of fins.

15. The semiconductor device package of claim 9 further comprising:
one or more first fasteners connected to the second substrate and the first hollow protrusion, the one or more first fasteners connected to the second substrate opposite where the second substrate is electrically connected to the first receiving port; and
one or more second fasteners connected to the third substrate and the second hollow protrusion, the one or more second fasteners connected to the third substrate opposite where the third substrate is electrically connected to the second receiving port.

16. The semiconductor device package of claim 15, wherein the one or more first fasteners and the one or more second fasteners include biasing elements configured to retain the orientation of the second substrate and third substrate relative to the first substrate.

17. The semiconductor device package of claim 1, wherein the one or more receiving ports are each through hole mounts electrically connected to the first substrate.

18. A semiconductor device package comprising:
a first substrate means for providing electrical communication to one or more electrical components coupled to the first substrate means;
one or more receiving means electrically connected to the first substrate means and for providing electrical communication between the first substrate means and one or more other substrate means;
one or more first storage means each for storing an amount of electrical charge, each of the one or more first storage means being electrically connected to the first substrate means by a respective electrical connection means;
a second substrate means for providing electrical communication to one or more electrical components coupled to the second substrate means, the second substrate means being electrically connected to the one or more receiving means and oriented generally perpendicular to the first substrate means;
one or more second storage means each for storing an amount of electrical charge, each of the one or more second storage means being electrically connected to the second substrate means by a respective electrical connection means;
a housing means for substantially enclosing each of the first substrate means, the second substrate means, the one or more receiving means, the one or more first storage means, and the one or more second storage means, the housing means comprising:
a bottom surface and a top surface, the first substrate means being positioned between the bottom surface and top surface of the housing;
a first hollow protrusion extending upwardly from the top surface of the housing means proximate one of the one or more receiving means, the second substrate means and the one or more second storage means being at least partially positioned within the first hollow protrusion.

19. The semiconductor device package of claim 18 further comprising:
a third substrate means for providing electrical communication to one or more electrical components coupled to the third substrate means, the third substrate means being electrically connected to the one or more receiving means and oriented generally perpendicular to the first substrate means and spaced from the second substrate means; and
one or more third storage means each for storing an amount of electrical charge, each of the one or more third storage means being electrically connected to the third substrate means by a respective electrical connection means.

20. A semiconductor device package comprising:
a first substrate having a top planar surface and a bottom planar surface substantially parallel to the top planar surface;
a first receiving port electrically connected to the first substrate;
a second receiving port spaced from the first receiving port and electrically connected to the first substrate;
one or more first NAND dies electrically connected to and mounted directly on the first substrate;
a second substrate having a top planar surface and a bottom planar surface, the second substrate electrically connected to the first receiving port such that the top planar surface of the second substrate is generally perpendicular to the top planar surface of the first substrate;
one or more second NAND dies electrically connected to and mounted directly on the second substrate;
a third substrate having a top planar surface and a bottom planar surface, the third substrate electrically connected to the second receiving port such that the top planar surface of the third substrate is generally perpendicular to the top planar surface of the first substrate;
one or more third NAND dies electrically connected to and mounted directly on the third substrate;
a housing substantially enclosing each of the first, second, and third substrates and each of the one or more first, second, and third NAND dies, the housing comprising:
a bottom surface and a top surface, the first substrate being positioned between the bottom surface and top surface of the housing;
a first hollow protrusion extending upwardly from the top surface of the housing proximate the first receiving port, the second substrate being at least partially positioned within the first hollow protrusion; and
a second hollow protrusion extending upwardly from the top surface of the housing proximate the second receiving port, the third substrate being at least partially positioned within the second hollow protrusion; and
a heat sink mounted on the top surface of the housing and including a plurality of fins, each of the plurality of fins being positioned between the first and second hollow protrusions of the housing.
